(19) United States
(12) Patent Application Publication
(10) Pub. No.: US 2005/0167797 A1
(43) Pub. Date: Aug. 4, 2005

(54) Structure package

(75) Inventor: Yin Yen Bong, Melaka (MY)

Correspondence Address: CONLEY ROSE, P.C., P. O. BOX 3267, HOUSTON, TX, 77253-3267, US

(73) Assignee: Advanpack Solutions Pte Ltd, Singapore (SG)

(21) Appl. No.: 10/766,971

(22) Filed: Jan. 29, 2004

(51) Int. Cl. H01L 23/02

(52) U.S. Cl. 257/678

(57) ABSTRACT

Wireless devices use protruding antennas for transmitting and receiving data signals. These protruding antennas govern the size and dimensions of these wireless devices. Perpetual reduction in the size of these wireless devices has resulted in an increasing need and desire to eliminate the protruding antennas. Solutions such as reducing the protruding antenna to a stub or using retractable antennas have limitations. The antenna stub sacrifices performance for size reduction. Additionally, the retractable antennas are usually physically separated from the integrated circuit. Electrical connectors interconnecting the external antenna and the integrated circuit can mechanically fail due to connector flexure. An improved integrated structure package is described according to embodiments of the invention where a plurality of pillar structures is used for inter-coupling and spatially displacing one or more semiconductor chips from a substrate to realise a stacked antenna configuration for space and footprint reduction. The good structural integrity of the plurality of pillars also provides mechanically robust electrical interconnections between circuits and antenna patterns formed on the substrate or in the semiconductor chip. The plurality of pillars can be further arranged for providing faraday shielding to an integrated circuit from electromagnetic interference. Dielectric material is further introduced between pairs of the plurality of pillars for forming capacitors for reducing parasitic capacitance.

### FIELD OF INVENTION

The present invention relates generally to a structure package. In particular, the invention relates to an integrated structure package for use as an integrated data transceiver for transceiving data signals.

### BACKGROUND

Wireless devices use protruding antennas for transmitting and receiving data signals. These protruding antennas govern the size and dimensions of these wireless devices. Perpetual reduction in the size of these wireless devices has resulted in an increasing need and desire to eliminate the protruding antennas. One immediate solution is to reduce the protruding antenna to a stub. Another immediate solution is to use retractable antennas in the wireless devices. However, both these immediate solutions have limitations.

The antenna stub sacrifices performance for size reduction, while the retractable antennas have to be fully extended during use to provide optimum performance. Furthermore, the retractable antennas are usually physically separated from the integrated circuit. Electrical connectors interconnecting the external antenna and the integrated circuit can mechanically fail due to connector flexure.

U.S. Pat. No. 6,239,752 B1 by Blanchard describes an integrated antenna structure where a metallic RF antenna forms part of a package structure for an RF transmit/receive chip, thereby eliminating needs for a separate package to house the RF transmit/receive chip and for wires or cables interconnecting the driver chip and the antenna. However, the size of the antenna in Blanchard is still governed by the size of the driver chip.

U.S. Pat. No. 6,424,315 B1 by Glenn describes a radio frequency identification (data) transceiver having a radio frequency (RF) antenna, which is fixed and electrically connected to an integrated circuit. The RF antenna in Glenn is a single thin film layer formed over a top surface of the integrated circuit with an insulating layer interfacing the integrated circuit and the RF antenna. In Glenn, multiple RF antenna layers may be used to form three-dimensional structures to improve antenna operations. However, interconnections between the layers of antenna increases in complexity with increased antenna layers. Complex processes are also required for forming the antenna layers and the insulating layers for supporting and segregating the antenna layers.

Hence, this clearly affirms a need for an improved integrated structure package.

### SUMMARY

In accordance with a first aspect of the invention, there is disclosed a structure package comprising:
a first semiconductor chip having a first integrated circuit;
a substrate having a first electrically conductive pattern formed thereon; and
a plurality of pillars, at least one of the plurality of pillars extending from the first semiconductor chip to the substrate for structurally intercoupling and spatially interdisplacing the first semiconductor chip and the substrate for forming a first channel therebetween,
wherein at least one of the plurality of pillars is for electrically communicating the first integrated circuit with the first electrically conductive pattern.

In accordance with a second aspect of the invention, there is disclosed a data transceiver comprising:
a first semiconductor chip having a data transceiver circuit;
a substrate having a first antenna pattern formed thereon; and
a plurality of pillars, at least one of the plurality of pillars extending from the first semiconductor chip to the substrate for structurally intercoupling and spatially interdisplacing the first semiconductor chip and the substrate for forming a first channel therebetween,
wherein at least one of the plurality of pillars is for electrically connecting and operatively communicating the data transceiver circuit with the first antenna pattern.

In accordance with a third aspect of the invention, there is disclosed a data transceiver comprising:
a first semiconductor chip having a first integrated circuit, the first integrated circuit comprising an antenna;
a substrate having a data transceiver circuit formed thereon; and
a plurality of pillars, at least one of the plurality of pillars extending from the first semiconductor chip to the substrate for structurally intercoupling and spatially interdisplacing the first semiconductor chip and the substrate for forming a first channel therebetween,
wherein at least one of the plurality of pillars is for electrically communicating the first integrated circuit with the data transceiver circuit.

### BRIEF DESCRIPTION OF THE DRAWINGS

Embodiments of the invention are described hereinafter with reference to the following drawings, in which:

FIG. 1 shows a partial front sectional view of a package structure according to a first embodiment of the invention with a channel formed between a semiconductor chip and a substrate when spatially inter-displaced by a plurality of pillars;

FIG. 2 shows a partial front sectional view of the package structure of FIG. 1 with the channel being filled with filler material;

FIG. 3 shows a partial front sectional view of the package structure of FIG. 1 according to a second embodiment of the invention with the semiconductor chip of FIG. 1 having a data transceiver circuit;

FIG. 4 shows a partial front view of the package structure of FIG. 1 with a plurality of semiconductor chips being formed in a stacked and structurally inter-coupled by a plurality of pillars further for providing electrical communication therebetween;

FIG. 5 shows a partial front sectional view of the package structure of FIG. 2 with a first plurality of pillars for structurally inter-coupling the semiconductor chip and the substrate and for providing electrical interconnections between the data transceiver circuit, a first antenna layer and a second antenna layer of FIG. 3, and a second plurality of pillars inter-abutting to form a wall for providing faraday shielding for the data transceiver circuit; and

FIG. 6 shows a partial front sectional view of FIG. 1 with dielectric material formed between at least one pair of the plurality of pillars of FIG. 1.

### DETAILED DESCRIPTION

A structure package is described hereinafter for addressing the foregoing problems.

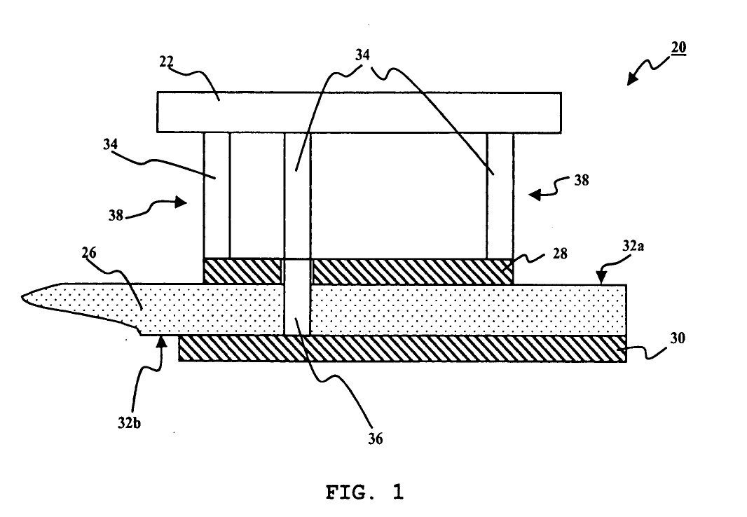

A first embodiment of the invention, a structure package 20 is described with reference to FIG. 1, which shows a partial front sectional view of the structure package.

As shown in FIG. 1, the structure package 20 comprises a semiconductor chip 22 containing an integrated circuit (not shown) and a substrate 26 having a first circuit layer 28 and a second circuit layer 30 formed thereon. The substrate 26 is preferably a printed circuit board (PCB). The substrate 26 has a first face 32a and a second face 32b outwardly opposing the first face 32a. The first circuit layer 28 is formed on the first face 32a and the second circuit layer 30 is formed on the second face of the substrate 26.

A plurality of pillars 34 extends from the semiconductor chip 22 to the substrate 26 for structurally inter-coupling and spatially inter-displacing the semiconductor chip 22 and the substrate 26. A first portion of the plurality of pillars 34 is for electrically communicating the integrated circuit with the first circuit layer 28 and a second portion of the plurality of pillars 34 is for providing signal communication between the integrated circuit and the second circuit layer 30.

The plurality of pillars 34 is spaced apart along the semiconductor chip 22 in addition to being disposed between the substrate 26 and the semiconductor chip 22.

When the semiconductor chip 22 is coupled to the substrate 26, the semiconductor chip 22 and the substrate 26 are arranged in a stacked configuration with the first face 32a of the substrate 26 opposing the semiconductor chip 22.

The structure package 20 further comprises an inter-connector 36, for example a via, being formed through the substrate 26 and the first circuit layer 28. The inter-connector 36 is for electrically connecting the second circuit layer 30 to one of the plurality of pillars 34 to thereby provide signal communication between the second circuit layer 30 and the integrated circuit. The inter-connector 36 is preferably electrically insulated from the first circuit layer 28. Alternatively, the inter-connector 36 is in signal communication with the first circuit layer 28.

Each of the plurality of pillars 34 is made of an electrically conductive material with a solder portion for attachment to one of the first circuit layer 28 and the second circuit layer 30 by a flip-chip re-flow process. The plurality of pillars 34 preferably has one of a rectangular or square shaped cross-section (not shown) but can alternatively assume other geometric shapes and elongated shapes.

The electrically conductive material is preferably copper. In addition, the plurality of pillars 34 can be further coated with one of oxide, chromium or nickel. The solder portion of each of the plurality of pillars 34 preferably has a material composition of one of 37% tin and 37% lead, 99% tin and 1% silver, and 100% tin. Alternatively, the solder portion of each of the plurality of pillars 34 is preferably of tin and lead composition with a tin concentration of within a range of 60% to 70%.

The plurality of pillars 34 functions both as an electrical connection between circuits and as a structure for supporting the semiconductor chip 22 on the substrate 26. The plurality of pillars 34 are used as electrical connectors in tandem with the plurality of apertures formed in the substrate 26 and the first circuit layer 28 for electrically connecting spatially separated circuits, for example, the first circuit layer 28 and the second circuit layer 30 being electrically connectable to the semiconductor chip without need for wire-bonding.

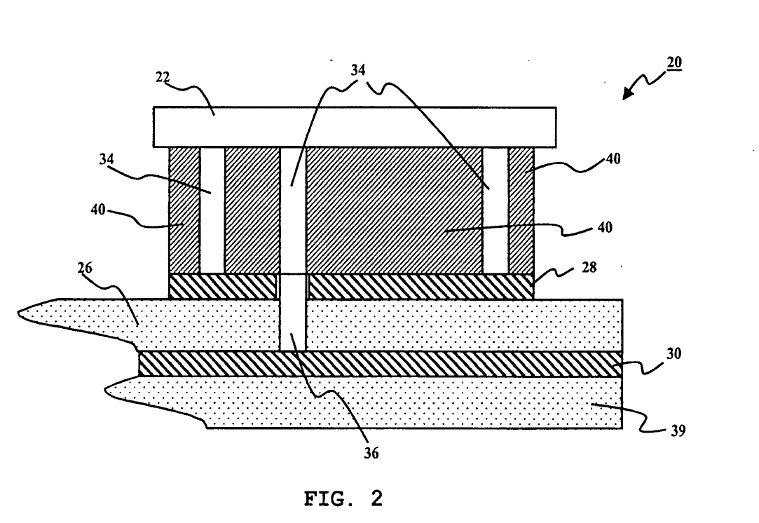

The plurality of pillars spatially inter-displaces the substrate 26 and the semiconductor chip 22 for forming a channel 38 therebetween. As shown in FIG. 2, the second circuit layer 30 is alternatively formed between the substrate 26 of FIG. 1 and another substrate 39 for forming a substrate sandwich structure. The channel 38 is preferably filled with a filler material 40.

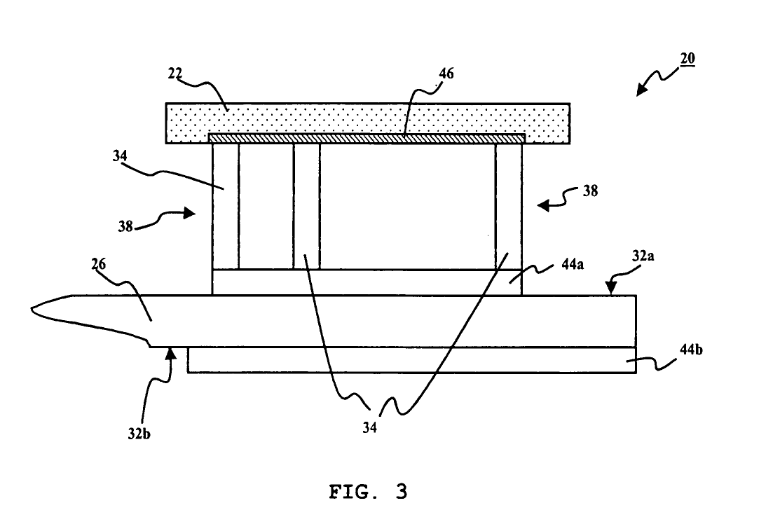

A second embodiment of the invention, a structure package 20 as seen in FIG. 3 comprises three main elements: a semiconductor chip 22 with an integrated circuit, a substrate 26 with a first circuit layer and a second circuit layer and a plurality of pillars 34. The descriptions in relation to the structural configurations of and positional relationships among the semiconductor chip 22, the substrate 26 and the plurality of pillars 34, and the electrical connections between the integrated circuit, the first circuit layer 28 and the second circuit layer 30 with reference to FIG. 1 are incorporated herein.

In the second embodiment, the first circuit layer and the second circuit layer as described in FIG. 1 are electrically conductive patterns for forming respectively a first antenna layer 44a and a second antenna layer 44b as shown in FIG. 3.

The first antenna layer 44a and the second antenna layer 44b function as transceiver antennas for contactless transmission and reception of data signals. A portion of the integrated circuit is a data transceiver circuit 46, for example an RFID transceiver circuit, for driving and data communicating with the first antenna layer 44a and the second antenna layer 44b. The substrate 26 electrically insulates the first electrically conductive pattern from the second electrically conductive pattern. Additionally, the plurality of pillars 34 spatially separates the first antenna layer 44a and the second antenna layer 44b from the integrated circuit while maintaining electrical connectivity thereto.

In the second embodiment, the structure package 20 of FIG. 3 is preferably encapsulated (not illustrated).

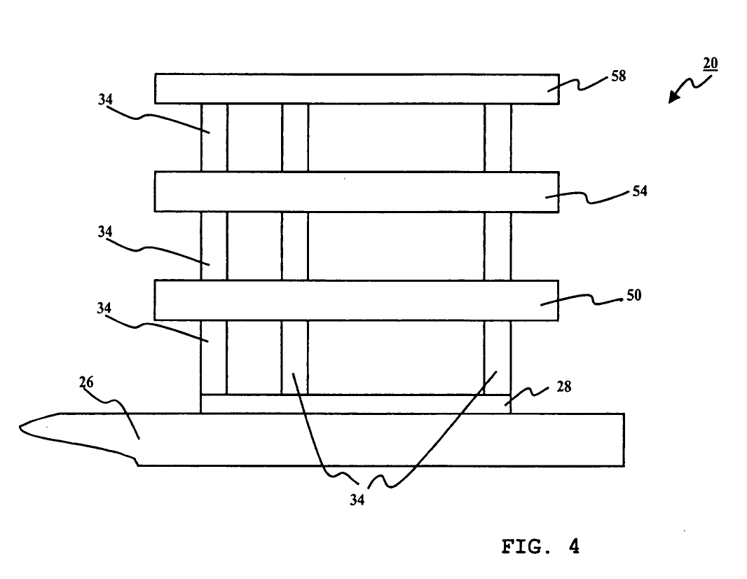

A third embodiment of the invention, a structure package 20 as seen in FIG. 4 comprises three main elements: a semiconductor chip 22 with a integrated circuit, a substrate 26 with a first antenna layer 44a and a second antenna layer 44b and a plurality of pillars 34. The descriptions in relation to the structural configurations of and positional relationships among the semiconductor chip 22, the substrate 26 and the plurality of pillars 34, and the electrical connections between the integrated circuit and the first electrically conductive pattern and with reference to FIG. 1 are incorporated herein. However, the second electrically conductive pattern described in the first embodiment is not incorporated in the third embodiment.

In the third embodiment, the semiconductor chip 22 and the integrated circuit of FIG. 1 are referred hereinafter as a first semiconductor chip 50 and a first integrated circuit respectively.

The structure package 20 further comprises a second semiconductor chip 54 having a second integrated circuit, and a third semiconductor chip 58 having a third integrated circuit. A portion of the plurality of pillars 34 further extends between the second semiconductor chip 54 and each of the first semiconductor chip 50 and the third semiconductor chip 58. The plurality of pillars 34 electrically connects at least a pair of the first integrated circuit, the second integrated circuit and the third integrated circuit for providing data communication therebetween. The portion of the plurality of pillars 34 is further for structurally inter-coupling and spatially inter-displacing the first semiconductor chip 50 and the second semiconductor chip 54, and for structurally inter-coupling and spatially inter-displacing the second semiconductor chip 54 and the third semiconductor chip 58.

The substrate 26, the first semiconductor chip 50, the second semiconductor chip 54 and the third semiconductor chip 58 are preferably arranged in a stacked configuration. The stacked configuration and the plurality of pillars 34 enables the structure package 20 to be compact while spatially separating the first integrated circuit, the second integrated circuit and the third integrated circuit. Footprint and space requirement of the structure package are also substantially reduced by the three-dimensional stacked configuration.

The filler material 40 further fills channels formed between the second semiconductor chip 54 and each of the first semiconductor chip 50 and the third semiconductor chip 58.

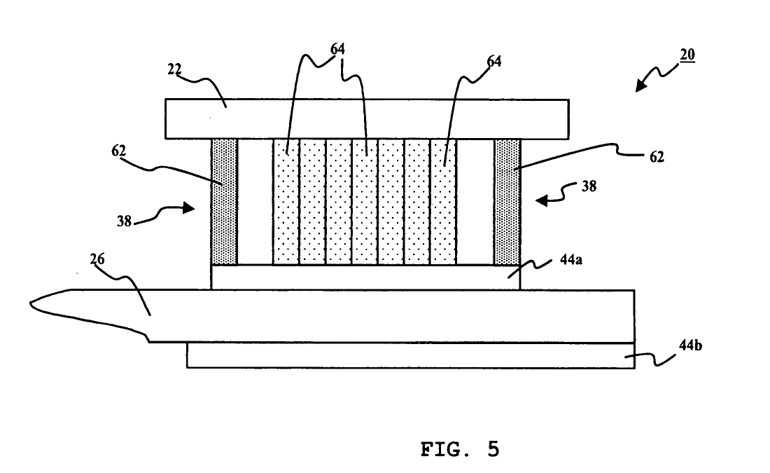

A fourth embodiment of the invention, a structure package 20 as seen in FIG. 5 comprises three main elements: a semiconductor chip 22 with a integrated circuit, a substrate 26 with a first antenna layer 44a and a second antenna layer 44b and a plurality of pillars 34. The descriptions in relation to the structural configurations of and positional relationships among the semiconductor chip 22, the substrate 26 and the plurality of pillars 34, and the electrical connections between the integrated circuit, the first electrically conductive pattern and the second electrically conductive pattern with reference to FIG. 3 are incorporated herein.

In the fourth embodiment, the plurality of pillars 34 is referred hereinafter as a first plurality of pillars 62. The structure package 20 further comprises a second plurality of pillars 64. The second plurality of pillars 64 extends between the first antenna layer 44a and the semiconductor chip 22 and is arranged for enclosing a shielded space therebetween. The shielded space is preferably box-shaped.

The second plurality of pillars 64 is arranged with each of the second plurality of pillars 64 abutting the nearest adjacent pillars for forming a wall along the periphery of the shielded space. The wall, the first antenna layer 44a and the semiconductor chip 22 enclose the shielded space for forming a faraday shield for shielding the integrated circuit from electromagnetic interference.

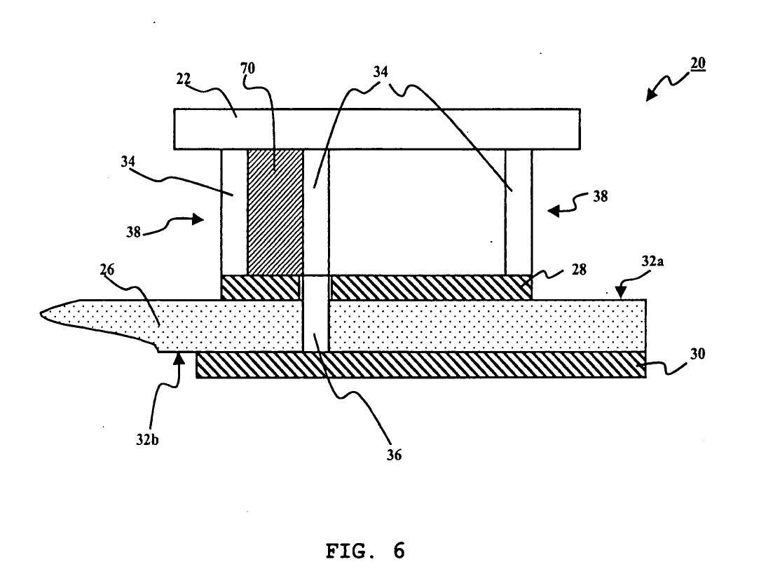

A fifth embodiment of the invention, a structure package 20 as seen in FIG. 6 comprises three main elements: a semiconductor chip 22 with a integrated circuit, a substrate 26 with a first antenna layer 44a and a second antenna layer 44b and a plurality of pillars 34. The descriptions in relation to the structural configurations of and positional relationships among the semiconductor chip 22, the substrate 26 and the plurality of pillars 34, and the electrical connections between the integrated circuit, the first electrically conductive pattern and the second electrically conductive pattern with reference to FIG. 1 are incorporated herein.

In the fifth embodiment, at least one pair of the plurality of pillars 34 has dielectric material 70 extending therebetween. The dielectric material 70 is preferably high-K dielectric material for establishing a high capacitance capacitor. The dimension of each of the plurality of pillars 34 and the distance between the at least one pair of the plurality of pillars 34 determines the capacitance value of the high-K dielectric material. Alternatively, the dielectric material 70 is preferably low-K dielectric material for reducing capacitance parasitics between the corresponding pair of the plurality of pillars 34.

In the foregoing manner, a structure package is described according to four embodiments of the invention for addressing the foregoing disadvantages of conventional structure packages. Although only three embodiments of the invention are disclosed, it will be apparent to one skilled in the art in view of this disclosure that numerous changes and/or modification can be made without departing from the scope and spirit of the invention.

1. A structure package comprising:
a first semiconductor chip having a first integrated circuit;
a substrate having a first electrically conductive pattern formed thereon, the first electrically conductive pattern being an antenna layer; and
a plurality of pillars, at least one of the plurality of pillars extending from the first semiconductor chip to the substrate for structurally intercoupling and spatially interdisplacing the first semiconductor chip and the substrate for forming a first channel therebetween,
wherein at least one of the plurality of pillars is for electrically communicating the first integrated circuit with the first electrically conductive pattern.

2. The structure package as in claim 1, the integrated circuit being a data transceiver circuit in operative communication with the first electrically conductive pattern.

3. The structure package as in claim 2, further comprising:
a second electrically conductive pattern, the first electrically conductive pattern and the second electrically conductive pattern being formed on two outwardly opposing faces of the substrate,
wherein at least one of the plurality of pillars is for electrically communicating the integrated circuit with the second electrically conductive pattern.

4. The structure package as in claim 3, the second electrically conductive pattern being an antenna layer and the integrated circuit being in operative communication with the second electrically conductive pattern.

5. The structure package as in claim 4, the first electrically conductive pattern and the second electrically conductive pattern are for transmitting and receiving data signals.

6. The structure package as in claim 2, further comprising:
at least one inter-connector formed through the substrate and the first electrically conductive pattern, the inter-connector for electrically connecting the second electrically conductive pattern to one of the plurality of pillars to thereby electrically inter-communicate the second electrically conductive pattern with the integrated circuit,
wherein the at least one inter-connector is one of electrically insulated from and in electrical communication with the first electrically conductive pattern.

7. The structure package as in claim 2, the first semiconductor chip and the substrate being arranged in a stacked configuration for forming the first channel between the substrate and the first semiconductor chip.

8. The structure package as in claim 7, the first channel being filled with a filler material.

9. The structure package as in claim 2, a portion of the plurality of pillars being spaced apart along the substrate when being disposed between the substrate and the first semiconductor chip.

10. The structure package as in claim 2, at least one of the plurality of pillars being formed from at least two conductive materials.

11. The structure package as in claim 10, one of the at least two conductive material being solder material.

12. The structure package as in claim 2, at least one pair of the plurality of pillars having dielectric material extending therebetween.

13. The structure package as in claim 12, the dielectric material being one of low-K dielectric material and high-K dielectric material.

14. The structure package as in claim 2, each of at least a portion of the plurality of pillars being formed abutting at least another one of the plurality of pillars along the substrate for enclosing a shielded space between the substrate and the first semiconductor chip, the shielded space for electrically shielding at least one of at least a portion of the first integrated circuit of the first semiconductor chip and at least a portion of the first electrically conductive pattern formed on the substrate.

15. The structure package as in claim 2, the first integrated circuit comprising an antenna.

16. The structure package as in claim 15, the first electrically conductive pattern being at least a portion of a data transceiver circuit.

17. The structure package as in claim 2, further comprising:
a second semiconductor chip having a second integrated circuit, at least one of the plurality of pillars extending from the second semiconductor chip to and spatially displacing the second semiconductor chip from one of the first semiconductor chip and the substrate,
wherein at least one of the plurality of pillars is for electrically communicating the second integrated circuit with at least one of the first integrated circuit and the first electrically conductive pattern.

18. The structure package as in claim 17, the first electrically conductive pattern being at least a portion of a data transceiver circuit and each of the first integrated circuit and the second integrated circuit comprising an antenna.

19. The structure package as in claim 17, the first semiconductor chip, the second semiconductor chip and the substrate being arranged in a stacked configuration with a second channel being formed between the second semiconductor chip and the first semiconductor chip.

20. The structure package as in claim 16, the second channel being filled with a filler material.

21. A data transceiver for transceiving data signals comprising:
a first semiconductor chip having a data transceiver circuit;
a substrate having a first antenna pattern formed thereon; and
a plurality of pillars, at least one of the plurality of pillars extending from the first semiconductor chip to the substrate for structurally intercoupling and spatially interdisplacing the first semiconductor chip and the substrate for forming a first channel therebetween,
wherein at least one of the plurality of pillars is for electrically connecting and operatively communicating the data transceiver circuit with the first antenna pattern.

22. The data transceiver as in claim 21, further comprising:
a second antenna pattern, the antenna pattern and the second antenna pattern being formed on two outwardly opposing faces of the substrate,
wherein at least one of the plurality of pillars is for electrically connecting and operatively communicating the data transceiver circuit with the second antenna pattern.

23. The data transceiver as in claim 22, the first antenna pattern and the second antenna pattern are for transmitting and receiving data signals.

24. The data transceiver as in claim 22, further comprising:
at least one inter-connector formed through the substrate and the first antenna pattern, the inter-connector for electrically connecting the second antenna pattern to one of the plurality of pillars to thereby electrically inter-communicate the second antenna pattern with the data transceiver circuit,
wherein the at least one inter-connector is one of electrically insulated from and in electrical communication with the first antenna pattern.

25. The data transceiver as in claim 22, the first semiconductor chip and the substrate being arranged in a stacked configuration for forming the first channel between the substrate and the first semiconductor chip.

26. A data transceiver for transceiving data signals comprising:
a first semiconductor chip having a first integrated circuit, the first integrated circuit comprising an antenna;
a substrate having a data transceiver circuit formed thereon; and
a plurality of pillars, at least one of the plurality of pillars extending from the first semiconductor chip to the substrate for structurally intercoupling and spatially interdisplacing the first semiconductor chip and the substrate for forming a first channel therebetween,
wherein at least one of the plurality of pillars is for electrically communicating the first integrated circuit with the data transceiver circuit.

27. The data transceiver as in claim 26, each of at least a portion of the plurality of pillars being formed abutting at least another one of the plurality of pillars along the substrate for enclosing a shielded space between the substrate and the first semiconductor chip, the shielded space for electrically shielding at least one of at least a portion of the first integrated circuit of the first semiconductor chip and at least a portion of the data transceiver circuit formed on the substrate.

28. The data transceiver as in claim 27, further comprising:
a second semiconductor chip having a second integrated circuit, the second integrated circuit comprising antenna, at least one of the plurality of pillars extending from the second semiconductor chip to and spatially displacing the second semiconductor chip from the first semiconductor chip,
wherein at least one of the plurality of pillars is for electrically communicating the second integrated circuit with at least one of the first integrated circuit and the first data transceiver circuit.

29. The data transceiver as in claim 28, the first semiconductor chip, the second semiconductor chip and the substrate being arranged in a stacked configuration with a second channel being formed between the second semiconductor chip and the first semiconductor chip.

30. The data transceiver as in claim 27, a portion of the plurality of pillars being spaced apart along the substrate when being disposed between the substrate and the first semiconductor chip.
